(19) United States
(12) Patent Application Publication
(10) Pub. No.: US 2026/0217306 A1
(43) Pub. Date: Jul. 30, 2026

(54) ELECTRIC POWER STEERING SYSTEM, CONTROL METHOD THEREOF, AND VEHICLE HAVING THE SAME

(71) Applicant: HL MANDO CORPORATION, Gyeonggi-do (KR)

(72) Inventor: Jaesang PARK, Gyeonggi-do (KR)

(21) Appl. No.: 19/235,484

(22) Filed: Jun. 11, 2025

(30) Foreign Application Priority Data
Jan. 24, 2025 (KR) 10-2025-0011597

(51) Int. Cl. B62D 5/04; B60Q 9/00; H02P 23/14

(52) U.S. Cl. CPC B62D 5/049; B60Q 9/00; B62D 5/046; B62D 5/0484; H02P 23/14

(57) ABSTRACT

The present embodiment relates to an electric power steering system, a control method thereof, and a vehicle having the same. More specifically, the present disclosure provides an electric power steering system, a control method thereof, and a vehicle having the same, which may detect and correct a current sensor calibration error by receiving a current measurement value of a current flowing in phases of a motor from a current sensor and comparing current measurement values corresponding to an input current based on the input current, thereby enabling more stable control of an inverter and a motor and preventing abnormal operation of the motor in advance.

### CROSS-REFERENCE TO RELATED APPLICATIONS

This application claims the priority of Korean Patent Application No. 10-2025-0011597 filed on Jan. 24, 2025, in the Korean Intellectual Property Office, the disclosure of which is incorporated herein by reference.

### BACKGROUND

### Field

The present embodiments relate to an electric power steering system, a control method thereof, and a vehicle having the same, which may detect and correct errors in a current sensor to minimize vibration and noise that may occur during vehicle operation.

### Description of the Related Art

Generally, a vehicle steering system is a device that allows the driver to arbitrarily change a direction of travel of a vehicle according to his/her intention.

For example, the steering system may change a steering angle of a wheel through a gearbox according to the rotation of a steering wheel, thereby changing the direction of travel of the vehicle.

The steering system may use a steering actuator, and the steering actuator may be broadly divided into a hydraulic type system that uses engine power to operate a hydraulic pump to assist a steering force, and an electric type system that uses an electric motor.

The hydraulic steering system detects the rotation of the steering wheel and uses a hydraulic pump to send hydraulic pressure to a driver, such as a rack bar or cylinder installed in the steering shaft, to assist steering force of a driver.

The electric power steering system has a structure that detects the rotation of the steering wheel and uses a motor to assist the operating force of the steering wheel or to enable steering.

Here, the electric power steering system indirectly measures the three-phase current of the motor through a current sensor, and uses the three-phase current to generate and output a control signal for controlling the motor.

However, according to this current sensing method, error occurs due to the external environment and long-term use, and in a case where the correction is not performed in a timely manner, vibration and noise problems may occur, causing discomfort to the driver.

### SUMMARY

The present embodiments provide an electric power steering system, a control method thereof, and a vehicle having the same, which may detect and correct a current sensor calibration error by receiving a current measurement value of a current flowing in phases of a motor from a current sensor and comparing current measurement values corresponding to an input current based on the input current, thereby enabling more stable control of an inverter and a motor and preventing abnormal operation of the motor in advance.

In one aspect, the present embodiment provides an electric power steering system including: a controller configured to generate and output a control signal for controlling a motor; an inverter configured to supply current to the motor according to the control signal; and a current sensor configured to detect a three-phase (U, V, and W) current supplied from the inverter to the motor, in which the controller is configured to receive a current measurement value detected from the current sensor, compare current measurement values of two phases (U-V, V-W, or W-U) among the current measurement values corresponding to an input current based on the input current, and determine a difference value, determine a calibration state of the current sensor as a normal state and output a confirmation signal for normality when the difference value is equal to or less than a preset reference value, and determine the calibration state of the current sensor as a fault state and output a warning signal for a current sensor calibration error when the difference value exceeds the preset reference value.

In another aspect, the present embodiment provides a control method of an electric power steering system, the control method including: a control signal outputting in which a controller generates and outputs a control signal for controlling a motor; a current supplying in which an inverter supplies current to the motor according to the control signal; a current detecting in which a current sensor detects a three-phase (U, V, W) current supplied from the inverter to the motor; and a warning signal outputting in which the controller receives a current measurement value detected from the current sensor, compares current measurement values of two phases (U-V, V-W, or W-U) among the current measurement values corresponding to an input current based on the input current to determine a difference value, determines a calibration state of the current sensor as a normal state and outputs a confirmation signal for normality when the difference value is equal to or less than a preset reference value, and determines the calibration state of the current sensor as a fault state and outputs a warning signal for a current sensor calibration error when the difference value exceeds the preset reference value.

In still another aspect, the present embodiment provides a vehicle including: a steering angle determinator configured to determine a steering angle based on a traveling path set by a traveling path setter; and an electric power steering system configured to assist an operating force of a steering wheel or enable steering based on the steering angle determined by the steering angle determinator, in which the electric power steering system includes a controller configured to generate and output a control signal for controlling a motor, an inverter configured to supply current to the motor according to the control signal, and a current sensor configured to detect a three-phase (U, V, and W) current supplied from the inverter to the motor, and the controller is configured to receive a current measurement value detected from the current sensor, compare current measurement values of two phases (U-V, V-W, or W-U) among the current measurement values corresponding to an input current based on the input current, and determine a difference value, determine a calibration state of the current sensor as a normal state and output a confirmation signal for normality when the difference value is equal to or less than a preset reference value, and determine the calibration state of the current sensor as a fault state and output a warning signal for a current sensor calibration error when the difference value exceeds the preset reference value.

According to the present embodiments, it is possible to provide an electric power steering system, a control method thereof, and a vehicle having the same capable of detecting and correcting a current sensor calibration error by receiving a current measurement value of a current flowing in phases of a motor from a current sensor and comparing current measurement values corresponding to an input current based on the input current, thereby enabling more stable control of an inverter and a motor and preventing abnormal operation of the motor in advance.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram illustrating a vehicle equipped with an electric power steering system according to the present embodiment.

FIG. 2 is a schematic diagram illustrating the structure of an electric power-assisted steering device of a vehicle.

FIG. 3 is a schematic diagram illustrating the structure of a steer-by-wire type steering device of a vehicle.

FIG. 4 is a circuit diagram illustrating an electric power steering system according to one embodiment.

FIG. 5 is a block diagram illustrating the electric power steering system according to one embodiment.

FIGS. 6A and 6B are graphs illustrating a process of correcting a current measurement value so that offset values of a current sensor according to one embodiment match.

FIGS. 7A and 7B are graphs illustrating a process of correcting the current measurement value so that the current measurement values of the current sensor match according to one embodiment.

FIG. 8 is a flowchart illustrating a control method of an electric power steering system according to the present embodiment.

FIG. 9 is a flow chart illustrating the control method of an electric power steering system according to the present embodiment.

FIG. 10 is a diagram for explaining an electric power steering system and a computer system of a vehicle according to the present embodiments.

### DETAILED DESCRIPTION OF THE EMBODIMENT

In the following description of examples or embodiments of the present disclosure, reference will be made to the accompanying drawings in which it is illustrated by way of illustration specific examples or embodiments that can be implemented, and in which the same reference numerals and signs can be used to designate the same or like components even when they are illustrated in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements or the like, but is used merely to distinguish the corresponding element from other elements.

When it is mentioned that a first element “is connected or coupled to”, “contacts or overlaps” or the like a second element, it should be interpreted that, not only may the first element “be directly connected or coupled to” or “directly contact or overlap” the second element, but a third element can also be “interposed” between the first and second elements, or the first and second elements can “be connected or coupled to”, “contact or overlap”, or the like each other via a fourth element. Here, the second element may be included in at least one of two or more elements that “are connected or coupled to”, “contact or overlap”, or the like each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes or the like are mentioned, it should be considered that numerical values for an elements or features, or corresponding information (for example, level, range, or the like) include a tolerance or error range that may be caused by various factors (for example, process factors, internal or external impact, noise, or the like) even when a relevant description is not specified. Further, the term “may” fully encompass all the meanings of the term “can”.

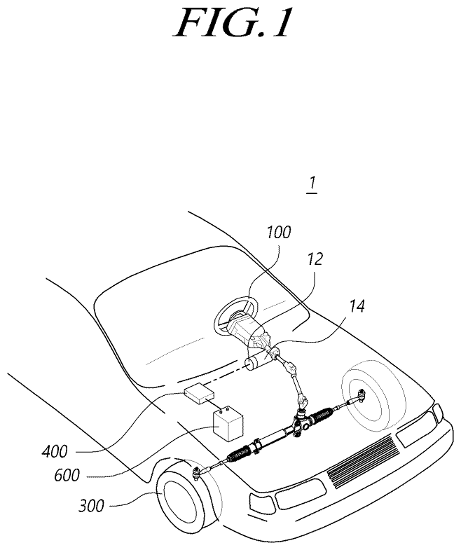

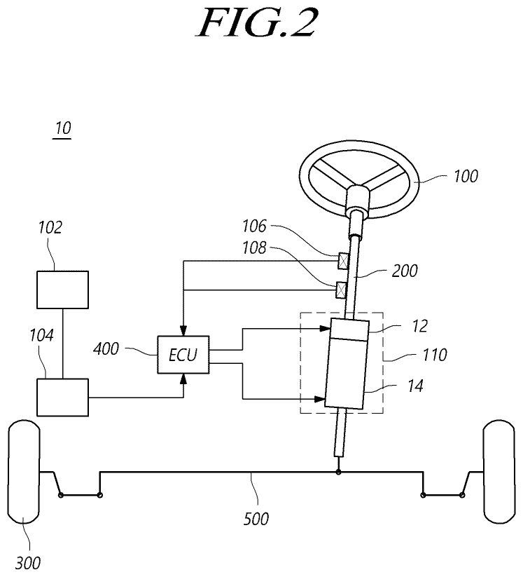

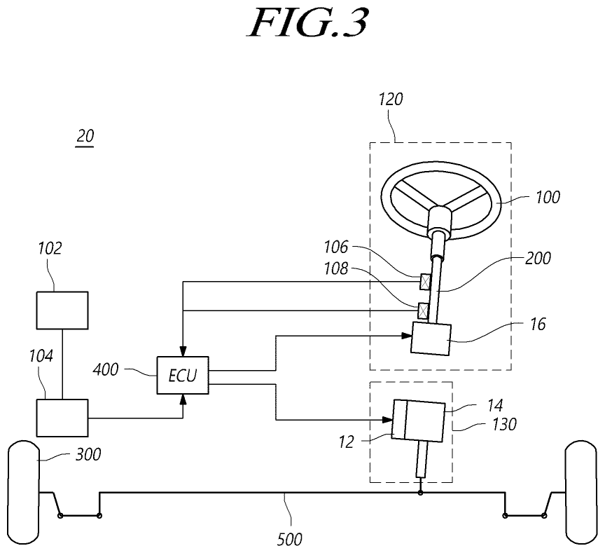

FIG. 1 is a schematic diagram illustrating a vehicle equipped with an electric power steering system according to the present embodiment, FIG. 2 is a schematic diagram illustrating the structure of an electric power-assisted steering device of a vehicle, and FIG. 3 is a schematic diagram illustrating the structure of a steer-by-wire type steering device of a vehicle.

Hereinafter, various embodiments are described in detail with reference to the attached drawings.

A vehicle 1 of the present embodiment may include a steering angle determinator 104 configured to determine a steering angle based on a traveling path set by a traveling path setter 102, and an electric power steering system configured to assist the operating force of a steering wheel 100 or enable steering based on the steering angle determined by the steering angle determinator 104.

In more detail, the traveling path setter 102 may set a traveling path by considering a current location, destination, traffic conditions, or the like, and transmit the set traveling path to the steering angle determinator 104.

In addition, the steering angle determinator 104 may determine the steering angle based on the traveling path set by the traveling path setter 102 and transmit a steering signal appropriate for the traveling situation to the controller 400.

In addition, the controller 400 may assist the operating force of the steering wheel 100 or enable steering according to the steering signal received from the steering angle determinator 104.

In this case, the electric power steering system may assist input of a driver or control the vehicle 1 completely autonomously.

The electric power steering systems include an electric power-assisted steering device that uses an electric motor, such as a motor, to assist the operating force of the steering wheel in order to provide convenience in driving, and a steer-by-wire (SBW) steering device that uses an electric motor, such as a motor, to steer the vehicle.

Referring to FIG. 2, in an electric power assist steering device 10 according to the present embodiment, an angle sensor 106 and a torque sensor 108 are coupled to one side of a steering shaft 200 connected to a steering wheel 100, and in a case where the driver operates the steering wheel 100, the angle sensor 106 and the torque sensor 108 that electronically detect the steering input of the driver transmit an electric signal to a controller 400, and the controller 400 generates a control signal for controlling a drive motor 14 and outputs the control signal to a steering actuator 110.

The controller 400 controls an inverter 12 of the drive motor 14 based on the electric signals transmitted from the angle sensor 106 and the torque sensor 108 and other electric signals transmitted from various sensors mounted on the vehicle.

In this case, the drive motor 14 moves a rack bar 500 that engages a pinion gear left and right to change the steering angle of a wheel 300.

Referring to FIG. 3, a steer-by-wire steering device 20 according to the present embodiments is equipped with a steering device 120 disposed close to the side of the driver and a steering actuator 130 positioned close to the wheel 300.

In the steer-by-wire type steering device 20, the angle sensor 106 and the torque sensor 108 are coupled to one side of the steering shaft 200 connected to a steering wheel 100. In a case where the driver operates the steering wheel 100, the angle sensor 106 and the torque sensor 108 detect the operation and transmit the electric signals to the controller 400. The controller 400 generates a control signal for controlling a reaction motor 16 and the drive motor 14 and outputs the control signal to the steering device 120 and the steering actuator 130.

The controller 400 controls the inverter 12 of the drive motor 14 based on the electric signals transmitted from the angle sensor 106 and the torque sensor 108 and other electric signals transmitted from various sensors mounted on the vehicle.

In this case, the drive motor 14 moves the rack bar 500 that engages the pinion gear left and right to change the steering angle of the wheel 300.

However, in the drawings of the present embodiments, for convenience of explanation, the angle sensor 106 and the torque sensor 108 provided in the steering shaft 200 are described and illustrated as steering sensors, but a speed sensor, a wheel steering angle sensor, a motor position sensor, various radars, lidars, camera image sensors, and the like for transmitting steering information to the controller 400 may be provided, and a detailed description of these various sensors will be omitted.

A motor 24 generates a rotating magnetic field using a three-phase AC voltage (voltage with a phase difference of 120° from each other) and thereby generates a rotating force, and may include the drive motor 14 or reaction motor 16.

An inverter 22 may control the speed and torque of the motor 24 by converting the direct current power of a power supply 600 into three-phase alternating current power.

The inverter 22 is a power conversion device that converts the direct current power into the three-phase alternating current power to drive the motor 24 and supplies the converted three-phase alternating current power to the motor 24, and a three-phase pulse width modulation (PWM) method maybe applied.

A current sensor 26 is disposed between the inverter 22 and the motor 24 or between the inverter 22 and ground, and may detect three-phase current.

In the present embodiment, the current sensor 26 may include a Hall Effect current sensor configured to measure current by using the interaction of a magnetic field and current, or a shunt resistance configured to measure voltage drop to determine current.

The current sensor 26 may be connected to the source terminal of the switching element constituting the inverter 22 and may measure the current flowing in each phase.

Here, the current sensor 26 may measure the current of two phases (U-V, V-W, or W-U) among the three phases U, V, and W, and determine the current value of the remaining one phase through the current values of the two phases.

For example, in a case where the current I_{U} of phase U=10 A (current flowing in the positive direction) and the current I_{V} of phase V =−5 A (current flowing in the negative direction), the current I_{W} of phase W may be determined as in Mathematical Expression 1.

$${I}_{W} = - ( {I}_{U} + {I}_{V} ) = - ( 10 A + ( - 5 A ) ) = - 5 A \qquad [ Mathematical Expression 1 ]$$

In the present embodiment, it may be implemented with two current sensors to measure only the current flowing in two phases, but it is not necessarily limited to this and may be implemented with three current sensors.

In this case, the combination of phases to which the current sensor 26 is connected may also be implemented in various ways.

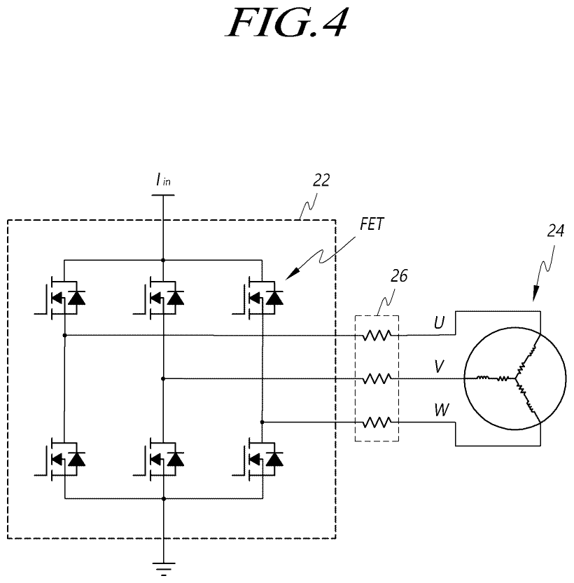

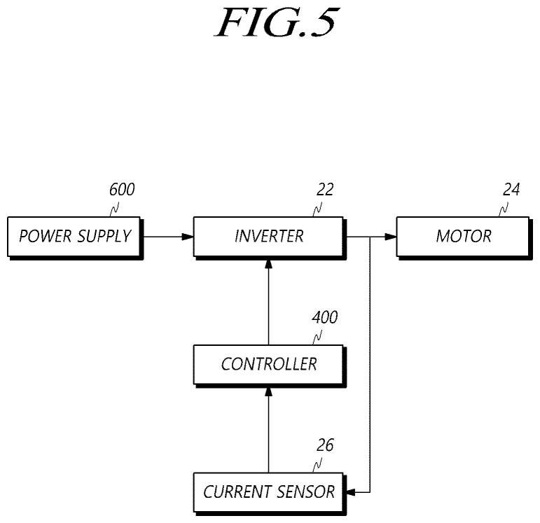

FIG. 4 is a circuit diagram illustrating an electric power steering system according to one embodiment, and FIG. 5 is a block diagram illustrating the electric power steering system according to one embodiment.

Referring to FIG. 4, the inverter 22 may generate a three-phase voltage (voltage with a phase difference of 120° from each other) using six switching elements.

In this case, the U phase, V phase, and W phase may each be composed of two switching elements (high-side and low-side).

The switching element may be implemented as a Field Effect Transistor (FET) or the like and be controlled on/off.

Specifically, as illustrated in FIG. 4, two switching elements controlling each phase are connected in series, two switching elements controlling each phase are connected in parallel, and a current sensor 26 may be connected to the source terminal of each of the upper (high-side) switching elements.

In this case, among the switching elements controlling each phase, the upper (high-side) switching element is connected to power, the lower (low-side) switching element connected in series with the upper (high-side) switching element is connected to ground, and the current sensor 26 may be connected between the lower (low-side) switching element and ground.

Each switching element is controlled by a Pulse Width Modulation (PWM) signal, and a total of six switching elements operate so that in a case where one switching element is turned ON in one phase, the other switching elements are turned OFF, generating a three-phase AC voltage with a phase difference of 120°.

For example, current is supplied to the U phase in a case where the upper (high-side) switching element of the U phase and the lower (low-side) switching element of the W phase are turned on, current is supplied to the V phase in a case where the upper (high-side) switching element of the V phase and the lower (low-side) switching element of the U phase are turned on, and current is supplied to the W phase in a case where the upper (high-side) switching element of the W phase and the lower (low-side) switching element of the V phase are turned on, so that a three-phase AC waveform may be generated.

Continuing, the electric power steering system according to one embodiment includes the controller 400 configured to generate and output a control signal for controlling the motor 24, the inverter 22 configured to supply current to the motor 24 according to the control signal, and the current sensor 26 configured to detect three-phase (U, V, W) current supplied from the inverter 22 to the motor 24. The controller 400 may be configured to receive the current measurement value detected from the current sensor 26, compare the current measurement values of two phases (U-V, V-W, or W-U) among the current measurement values corresponding to an input current Iᵢₙ based on the input current Iᵢₙ to determines a difference value, determine a calibration state of the current sensor 26 as a normal state and output a confirmation signal for normality when the difference value is equal to or less than a preset reference value, and determine the calibration state of the current sensor 26 as a fault state and output a warning signal for a current sensor calibration error when the difference value exceeds the preset reference value.

The controller 400 may compare a target value (speed, torque, position, or the like) with a feedback value (current state of the motor) and generate and output the control signal for controlling the motor 24.

In this case, the controller 400 may generate a control signal to drive the motor 24 to a desired state by executing a control algorithm (PID control, vector control) based on an error value obtained by subtracting the feedback value from the target value.

That is, the controller 400 may detect the state of the motor 24, such as current, voltage, speed, and position, in real time and reflect the state in the control algorithm to continuously adjust the operation of the motor 24.

Here, the control signal is output in the form of PWM and transmitted to the gate driver, and the gate driver amplifies the voltage and current of the PWM signal to control the switching element to switch ON/OFF at the correct timing.

The inverter 22 may supply current to the motor 24 according to a control signal, and control the speed and torque of the motor 24 by converting direct current power into three-phase alternating current.

The inverter 22 may generate a three-phase voltage (voltage with a phase difference of 120° from each other) using six switching elements.

The current sensor 26 detects the three-phase (U, V, W) current supplied from the inverter 22 to the motor 24, and may include a Hall Effect current sensor configured to measure current using the interaction of a magnetic field and current, or a shunt resistance configured to measure the voltage drop to determine current.

In one embodiment, the controller 400 may receive the current measurement value detected from the current sensor 26, compare the current measurement values of two phases (U-V, V-W, or W-U) among the current measurement values corresponding to the input current Iᵢₙ based on the input current Iᵢₙ to determine the difference value, determine the calibration state of the current sensor 26 as the normal state and output the confirmation signal for normality in a case where the difference value is equal to or less than the preset reference value, and determine the calibration state of the current sensor 26 as a fault state and output the warning signal for the current sensor calibration error in a case where the difference value exceeds the preset reference value.

That is, in a case where the controller 400 determines the calibration state of the current sensor 26 and determines the calibration state as the normal state, the controller may output the confirmation signal for normality, and in a case where the controller 400 determines the calibration state as the fault state, the controller may output the warning signal for the current sensor calibration error.

In this case, when it is determined that the calibration state of the current sensor 26 is determined as the normal state, the controller 400 may be configured to maintain the operation of the motor 24, and when it is determined that the calibration state is determined as the fault state, the controller may be configured to restrict the operation of the motor 24.

Here, the controller 400 may receive the current values of two phases (U-V, V-W, or W-U) measured from the current sensor 26, and compare the measured values of the two phases to infer the current value of the remaining one phase.

For example, the controller 400 may determine the difference between the U-phase current measurement value and the V-phase current measurement value corresponding to the input current Iᵢₙ as in Mathematical Expression 2 to determine the difference value.

$$[ Mathematical Expression 2 ]$$

$$Difference value = \vert U - phase current measurement value - V - phase current measurement value \vert$$

Here, the calibration state of the current sensor 26 may be determined as the normal state and the confirmation signal for normality may be output in a case where the difference value is equal to or less than the preset reference value, and the calibration state of the current sensor 26 may be determined as the fault state and the warning signal for the current sensor calibration error may be output in a case where the difference value exceeds the preset reference value.

In this case, the controller 400 may be configured to maintain the operation of the motor 24 when it is determined to be in the normal state according to the calibration state of the current sensor 26, and may be configured to restrict the operation of the motor 24 when it is determined to be in the fault state.

Meanwhile, the controller 400 may be configured to determine whether offset values (zero points) of two phases (U-V, V-W, or W-U) among the three phases U, V and W detected by the current sensor 26 match, and may be configured to correct the current measurement value so that the offset values of the phases match when the offset values do not match.

That is, when the offset values do not match, the controller 400 may be configured to adjust and correct any one of the current measurement values by the difference between the offset values of the two phases so that the offset values of the phases match.

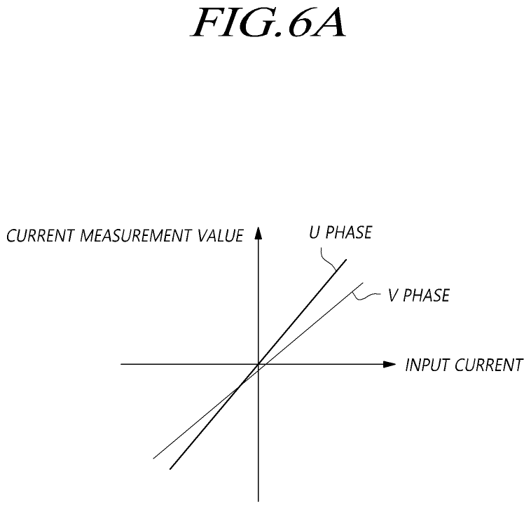

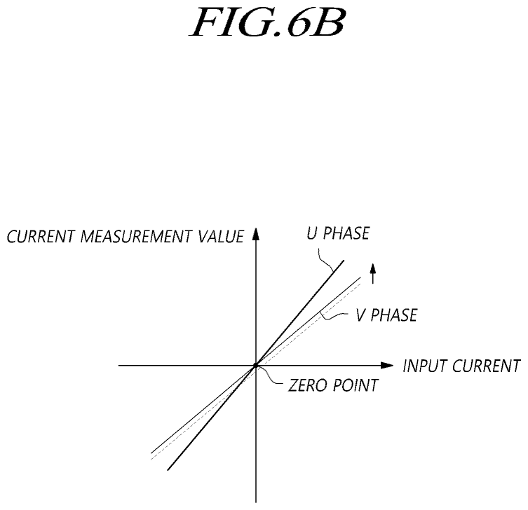

FIGS. 6A and 6B are graphs illustrating a process of correcting the current measurement value so that the offset values of the current sensor according to one embodiment match.

For example, as illustrated in FIG. 6A, in a case where the offset values of the U phase and the V phase do not match, the current measurement value of the V phase may be adjusted by the difference between the offset values of the U phase and the V phase so that the offset values of the U phase and the V phase match, as illustrated in FIG. 6B, thereby making corrections.

In addition, the controller 400 may configured to determine whether the current measurement values of two phases (U-V, V-W, or W-U) among the three phases (U, V, and W) detected by the current sensor 26 match, and when the current measurement values do not match, the controller may be configured to correct the current measurement values so that the current measurement values of the phases match.

That is, when the current measurement values do not match, in order to match the current measurement values of the phases, the controller 400 may be configured to obtain an absolute value by multiplying ½ by a value obtained by subtracting one of the current measurement values of the two phases from the other, subtract the absolute value from the current measurement value measured higher of the current measurement values, and add the absolute value to the current measurement value measured lower, thereby correcting the current measurement values so that the current measurement values of the two phases match.

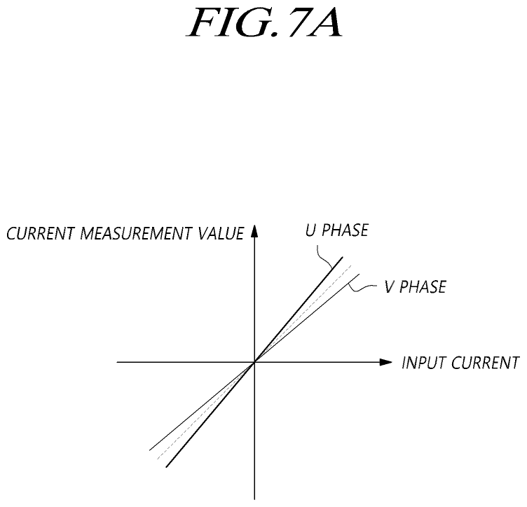

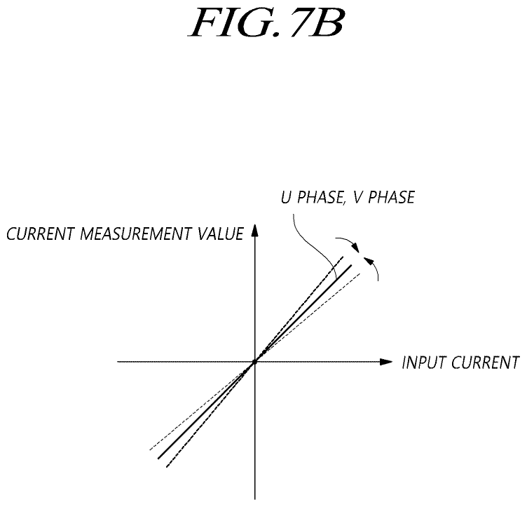

FIGS. 7A and 7B are graphs illustrating a process of correcting current measurement values so that the current measurement values of the current sensor match according to one embodiment.

For example, as illustrated in FIG. 7A, in a case where the current measurement values of the U phase and the V phase do not match, in order to match the current measurement values of the U phase and the V phase, the controller 400 may obtain an absolute value by multiplying ½ by a value obtained by subtracting the current measurement value of the V phase from the current measurement value of the U phase of the current measurement values of the U phase and V phase, subtract the absolute value from the current measurement value of the U phase, and add the absolute value to the current measurement value of the V phase, thereby correcting the current measurement values so that the current measurement values of the U phase and V phase match, as illustrated in FIG. 7B.

In this way, in the present embodiment, the current measurement value of the current flowing in each phase of the motor 24 is received from the current sensor 26, the current measurement values corresponding to the input current Iᵢₙ are compared based on the input current Iᵢₙ, and the calibration error of the current sensor 26 is detected and corrected, thereby enabling more stable control of the inverter 22 and the motor 24 and preventing abnormal operation of the motor 24 in advance.

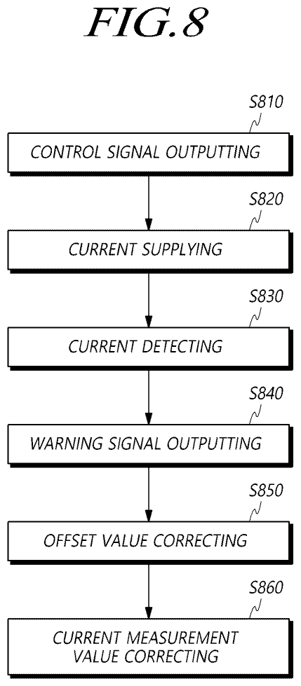

FIG. 8 is a flowchart illustrating a control method of an electric power steering system according to the present embodiment.

In another aspect, the control method of the electric power steering system of the present embodiment may include a control signal outputting (S810) in which the controller 400 generates and outputs a control signal for controlling the motor 24, a current supplying (S820) in which the inverter 22 supplies current to the motor 24 according to the control signal, a current detecting (S830) in which the current sensor 26 detects the three phase (U, V, W) current supplied from the inverter 22 to the motor 24, a warning signal outputting (S840) in which the controller 400 receives the current measurement value detected from the current sensor 26, compares the current measurement values of two phases (U-V, V-W, or W-U) among the current measurement values corresponding to the input current Iᵢₙ based on the input current Iᵢₙ to determine the difference value, determines the calibration state of the current sensor 26 as the normal state and outputs the confirmation signal for normality when the difference value is equal to or less than a preset reference value, and determines the calibration state of the current sensor 26 as the fault state and outputs the warning signal for the calibration error of the current sensor 26 when the difference value exceeds the preset reference value, an offset value correcting (S850) in which the controller 400 determines whether the offset values (zero points) of two phases (U-V, V-W, or W-U) among the three phases (U, V, and W) detected by the current sensor 26 match and corrects the current measurement values so that the offset values of the phases match when the offset values do not match, and a current measurement value correcting (S860) in which the controller 400 determines whether the current measurement values of two phases (U-V, V-W, or W-U) among the three phases (U, V and W) detected by the current sensor 26 match and corrects the current measurement values so that the current measurement values of the phases match when the current measurement values do not match.

Referring to FIG. 8, in the control signal outputting (S810), the controller 400 may compare the target value (speed, torque, position, or the like) with the feedback value (current state of the motor) and generate and output the control signal for controlling the motor 24.

In this case, the controller 400 may generate the control signal to drive the motor 24 to a desired state by executing a control algorithm (PID control, vector control) based on the error value obtained by subtracting the feedback value from the target value.

That is, the controller 400 may detect the state of the motor 24, such as current, voltage, speed, and position, in real time and reflect the state in the control algorithm to continuously adjust the operation of the motor 24.

Here, the control signal is output in the form of PWM and transmitted to the gate driver, and the gate driver amplifies the voltage and current of the PWM signal to control the switching element to switch ON/OFF at the correct timing.

In the current supplying (S820), the inverter 22 may supply current to the motor 24 according to the control signal.

That is, in the current supplying (S820), the inverter 22 may convert the direct current power into three-phase alternating current power to control the speed and torque of the motor 24.

The inverter 22 may generate a three-phase voltage (voltage with a phase difference of 120° from each other) using six switching elements.

In the current detecting (S830), the current sensor 26 may detect the three-phase (U, V, W) current supplied from the inverter 22 to the motor 24.

In this case, the current sensor 26 may include a Hall Effect current sensor configured to measure current by using the interaction between a magnetic field and current, or the shunt resistance configured to measure voltage drop to determine current.

In the warning signal outputting (S840), the controller 400 may receive the current measurement value detected from the current sensor 26, compare the current measurement values of two phases (U-V, V-W, or W-U) among the current measurement values corresponding to the input current Iᵢₙ based on the input current Iᵢₙ to determine the difference value, determine the calibration state of the current sensor 26 as the normal state and output the confirmation signal for normality in a case where the difference value is equal to or less than a preset reference value, and determine the calibration state of the current sensor 26 as the fault state and output the warning signal for the calibration error of the current sensor 26 in a case where the difference value exceeds the preset reference value.

That is, in the warning signal outputting (S840), in a case where it is determined that the calibration state of the current sensor 26 is determined as the normal state, the controller 400 may out the confirmation signal for normality, and in a case where it is determined that the calibration state is determined as the fault state, the controller may output the warning signal for the current sensor calibration error.

In this case, in the warning signal outputting (S840), when it is determined that the calibration state of the current sensor 26 is determined as the normal state, the controller 400 may be congirued to maintain the operation of the motor 24, and when it is determined that the calibration state is determined as the fault state, the controller may be configured to restrict the operation of the motor 24.

Here, the controller 400 may receive the current values of two phases (U-V, V-W, or W-U) measured from the current sensor 26, and compare the measured values of the two phases to infer the current value of the remaining one phase.

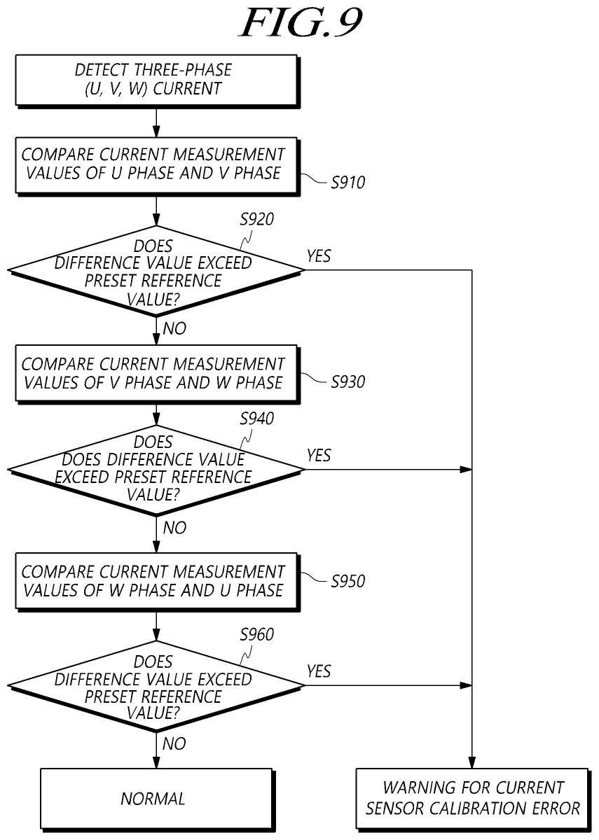

FIG. 9 is a flowchart illustrating the control method of an electric power steering system according to the present embodiment.

Referring to FIG. 9, in the warning signal outputting (S840), the controller 400 may be configured to receive the current measurement value detected from the current sensor 26, compare the current measurement values of the U phase and V phase among the current measurement values corresponding to the input current Iᵢₙ based on the input current Iᵢₙ to determine the difference value, determine the calibration state of the current sensor 26 as the normal state and maintain the operation of the motor 24 when the difference value is equal to or less than a preset reference value, and determine the calibration state of the current sensor 26 as the fault state and restrict the operation of the motor 24 when the difference value exceeds the preset reference value (S910 and S920).

And, in the warning signal outputting (S840), when it is determined that the current measurement values of the U phase and V phase are normal, the controller 400 may be configured to compare the current measurement values of the V phase and W phase to determine the difference value, determine the calibration state as the normal state and maintain the operation of the motor 24 when the difference value is equal to or less than the preset reference value, and determine the calibration state as the fault state and restrict the operation of the motor 24 when the difference value exceeds preset reference value (S930 and S940).

Moreover, in the warning signal outputting (S840), when it is determined that the current measurement values of the V phase and W phase are normal, the controller 400 may be configured to compare the current measurement values of the W phase and U phase to determine the difference value, determine the calibration state as the normal state and maintain the operation of the motor 24 when the difference value is equal to or less than the preset reference value, and determine the calibration state as the fault state and restrict the operation of the motor 24 when the difference value exceeds preset reference value (S950 and S960).

Accordingly, in the warning signal outputting (S840), the current measurement values of the U phase and the V phase, the V phase and the W phase, and the W phase and the U phase are compared to determine the calibration state of the current sensor 26, the operation of the motor 24 may be maintained when the calibration state is determined to be in the normal state, and the operation of the motor 24 may be restricted when the calibration state is determined to be in the fault state.

In the offset value correcting (S850) after the current detecting (S830) or after the warning signal outputting (S840), the controller 400 may configured to determine whether the offset values (zero points) of two phases (U-V, V-W, or W-U) among the three phases U, V, and W detected by the current sensor 26 match and correct the current measurement values so that the offset values of the phases match when the offset values do not match.

That is, in the offset value correcting (S850), when the offset values do not match, one of the current measurement values may be adjusted and corrected by the difference between the offset values of the two phases so that the offset values of the phases match.

Continuing, in the current measurement value correcting (S860) after the offset value correcting (S850), the controller 400 may be configured to determine whether the current measurement values of two phases (U-V, V-W, or W-U) among the three phases U, V, and W detected by the current sensor 26 match and correct the current measurement values so that the current measurement values of the phases match when the current measurement values do not match.

That is, in the current measurement value correcting (S860), when the current measurement values do not match, in order to match the current measurement values of the phases, the controller 400 may be configured to obtain an absolute value by multiplying ½ by a value obtained by subtracting one of the current measurement values of the two phases from the other, subtract the absolute value from the current measurement value measured higher of the current measurement values, and add the absolute value to the current measurement value measured lower, thereby correcting the current measurement values so that the current measurement values of the two phases match.

According to the present embodiments, the current measurement value of the current flowing in each phase of the motor 24 is received from the current sensor 26, the current measurement values corresponding to the input current Iᵢₙ are compared based on the input current Iᵢₙ, and the current sensor calibration error is detected and corrected, thereby enabling more stable control of the inverter 22 and the motor 24 and preventing abnormal operation of the motor 24 in advance.

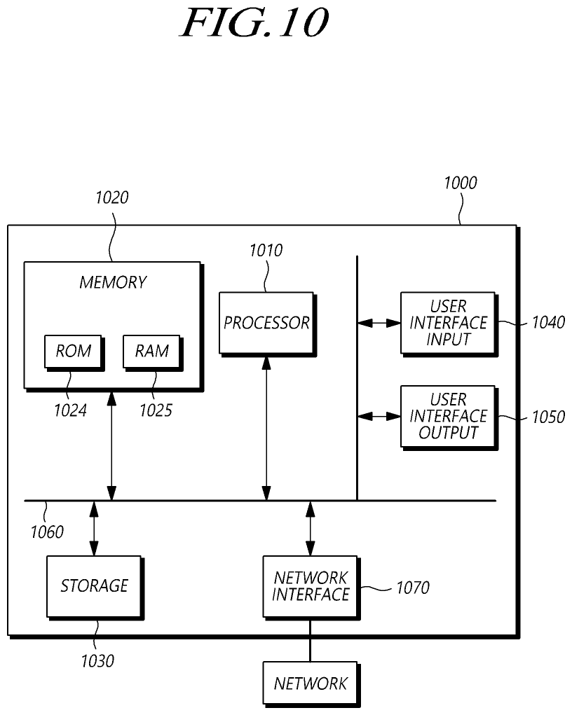

FIG. 10 is a diagram for explaining an electric power steering system and a computer system of a vehicle according to the present embodiments.

Referring to FIG. 10, the above-described embodiments may be implemented in a computer system, for example, as a computer-readable recording medium. As illustrated in the drawing, a computer system 1000 of the electric power steering system and the vehicle may include at least one or more elements of one or more processors 1010, a memory 1020, a storage 1030, a user interface input 1040, and a user interface output 1050, which may communicate with each other via a bus 1060. In addition, the computer system 1000 may also include a network interface 1070 for connecting to a network. The processor 1010 may be a CPU or a semiconductor device that executes processing instructions stored in the memory 1020 and/or the storage 1030. The memory 1020 and the storage 1030 may include various types of volatile/nonvolatile storage media. For example, the memory may include ROM 1024 and RAM 1025.

Accordingly, the present embodiments may be implemented as a computer-implemented method or as a non-volatile computer storage medium having computer-executable instructions stored thereon. In a case where the instructions are executed by a processor, the method according to at least one embodiment of the present embodiments may be performed.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments illustrated, but is to be accorded the widest scope consistent with the claims.

What is claimed is:

1. An electric power steering system comprising:
a controller configured to generate and output a control signal for controlling a motor;
an inverter configured to supply current to the motor according to the control signal; and
a current sensor configured to detect a three-phase (U, V, and W) current supplied from the inverter to the motor,
wherein the controller is configured to:
receive a current measurement value detected from the current sensor, compare current measurement values of two phases (U-V, V-W, or W-U) among the current measurement values corresponding to an input current based on the input current, and determine a difference value,
determine a calibration state of the current sensor as a normal state and output a confirmation signal for normality when the difference value is equal to or less than a preset reference value, and
determine the calibration state of the current sensor as a fault state and output a warning signal for a current sensor calibration error when the difference value exceeds the preset reference value.

2. The electric power steering system of claim 1, wherein the controller is configured to:
maintain an operation of the motor when the calibration state is determined to be the normal state, and
restrict the operation of the motor when the calibration state is determined to be the fault state.

3. The electric power steering system of claim 1, wherein the controller is configured to determine whether the offset values (zero points) of two phases (U-V, V-W, or W-U) among the three phases (U, V, and W) detected by the current sensor match, and correct the current measurement value so that the offset values of the phases match when the offset values do not match.

4. The electric power steering system of claim 3, wherein when the offset values do not match, the controller is configured to adjust and correct the current measurement value of any one phase by a difference between the offset values of the two phases so that the offset values of the phases match.

5. The electric power steering system of claim 4, wherein the controller is configured to determine whether the current measurement values of two phases (U-V, V-W, or W-U) among the three phases (U, V, and W) detected by the current sensor match, and when the current measurement value does not match, the controller is configured to correct the current measurement values so that the current measurement values of the phases match.

6. The electric power steering system of claim 5, wherein when the current measurement values do not match, in order to match the current measurement values of the phases, the controller is configured to obtain an absolute value by multiplying ½ by a value obtained by subtracting one of the current measurement values of the two phases from the other, subtract the absolute value from the current measurement value measured higher of the current measurement values, and add the absolute value to the current measurement value measured lower, thereby correcting the current measurement values so that the current measurement values of the two phases match.

7. The electric power steering system of claim 1, wherein the current sensor is a Hall Effect current sensor configured to measure current by using interaction of a magnetic field and current.

8. The electric power steering system of claim 1, wherein the current sensor includes a shunt resistance configured to measure voltage drop to determine current.

9. A control method of an electric power steering system, the control method comprising:
a control signal outputting in which a controller generates and outputs a control signal for controlling a motor;
a current supplying in which an inverter supplies current to the motor according to the control signal;
a current detecting in which a current sensor detects three-phase (U, V, W) current supplied from the inverter to the motor; and
a warning signal outputting in which the controller receives a current measurement value detected from the current sensor, compares current measurement values of two phases (U-V, V-W, or W-U) among the current measurement values corresponding to an input current based on the input current to determine a difference value, determines a calibration state of the current sensor as a normal state and outputs a confirmation signal for normality when the difference value is equal to or less than a preset reference value, and determines the calibration state of the current sensor as a fault state and outputs a warning signal for a current sensor calibration error when the difference value exceeds the preset reference value.

10. The method of claim 9, wherein in the warning signal outputting, the controller is configured to maintain an operation of the motor when the calibration state is determined to be the normal state, and restrict the operation of the motor when the calibration state is determined to be the fault state.

11. The method of claim 9, wherein in the warning signal outputting, the controller is configured to
receive the current measurement value detected from the current sensor and compare the current measurement values for the U phase and the V phase among the current measurement values corresponding to the input current based on the input current to determine a difference value,
determine the calibration state as the normal state and maintain the operation of the motor when the difference value is equal to or less than a preset reference value, and
determine the calibration state as the fault state and restrict the operation of the motor when the difference value exceeds the preset reference.

12. The method of claim 11, wherein in the warning signal outputting, the controller is configured to
compare the current measurement values for the V phase and the W phase to determine the difference value when it is determined that the current measurement values for the U phase and the V phase are determined as the normal state,
determine the calibration state as the normal state and maintains the operation of the motor when the difference value is equal to or less than a preset reference value, and
determine the calibration state as the fault state and restricts the operation of the motor when the difference value exceeds the preset reference.

13. The method of claim 12, wherein in the warning signal outputting, the controller is configured to
compare the current measurement values for the W phase and the U phase to determine the difference value when it is determined that the current measurement values for the V phase and the W phase are determined as the normal state,
determine the calibration state as the normal state and maintains the operation of the motor when the difference value is equal to or less than a preset reference value, and
determine the calibration state as the fault state and restricts the operation of the motor when the difference value exceeds the preset reference.

14. The method of claim 9, further comprising determining, after the warning signal outputting, offset value correcting in which the controller determines whether offset values (zero points) of two phases (U-V, V-W, or W-U) among the three phases (U, V, and W) detected by the current sensor match and corrects the current measurement value so that the offset values of the phases match when the offset values do not match.

15. The method of claim 14, wherein in the offset value correcting, when the offset values do not match, the current measurement value of any one phase is adjusted and corrected by a difference between the offset values of the two phases so that the offset values of the phases match.

16. The method of claim 15, further comprising, after the offset value correction, a current measurement value correcting in which the controller is configured to determine whether the current measurement values of two phases (U-V, V-W, or W-U) among the three phases (U, V, and W) detected by the current sensor match, and when the current measurement value does not match, the controller is configured to correct the current measurement values so that the current measurement values of the phases match.

17. The method of claim 16, wherein the current measurement value correction, when the current measurement values do not match, in order to match the current measurement values of the phases, the controller is configured to obtain an absolute value by multiplying ½ by a value obtained by subtracting one of the current measurement values of the two phases from the other, subtract the absolute value from the current measurement value measured higher of the current measurement values, and add the absolute value to the current measurement value measured lower, thereby correcting the current measurement values so that the current measurement values of the two phases match.

18. The method of claim 9, wherein the current sensor is a Hall Effect current sensor configured to measure current by using interaction of a magnetic field and current.

19. The method of claim 9, wherein the current sensor includes a shunt resistance configured to measure voltage drop to determine current.

20. A vehicle comprising:
a steering angle determinator configured to determine a steering angle based on a traveling path set by a traveling path setter; and an electric power steering system configured to assist an operating force of a steering wheel or enable steering based on the steering angle determined by the steering angle determinator,
wherein the electric power steering system includes
a controller configured to generate and output a control signal for controlling a motor,
an inverter configured to supply current to the motor according to the control signal, and
a current sensor configured to detect a three-phase (U, V, and W) current supplied from the inverter to the motor, and
the controller is configured to:
receive a current measurement value detected from the current sensor, compare current measurement values of two phases (U-V, V-W, or W-U) among the current measurement values corresponding to an input current based on the input current, and determine a difference value,
determine a calibration state of the current sensor as a normal state and output a confirmation signal for normality when the difference value is equal to or less than a preset reference value, and
determine the calibration state of the current sensor as a fault state and output a warning signal for a current sensor calibration error when the difference value exceeds the preset reference value.
